(19) United States
(12) Patent Application Publication
(10) Pub. No.: US 2002/0197817 A1
(43) Pub. Date: Dec. 26, 2002

(54) Methods for forming a capacitor of a semiconductor device

(75) Inventors: Cheol Kyu Bok, Seoul (KR); Ki Soo Shin, Kyoungki-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 10/140,533

(22) Filed: May 6, 2002

(30) Foreign Application Priority Data
Jun. 26, 2001 (KR) 2001-36597

(51) Int. Cl. H01L 21/20; H01L 21/8242

(52) U.S. Cl. 438/397; 438/254

(57) ABSTRACT

The present invention discloses methods for forming a capacitor of a semiconductor device, including the steps of: forming a storage electrode conductive layer on a semiconductor substrate; coating a photoresist film on the storage electrode conductive layer; exposing the photoresist film to light according to an exposure process using a storage electrode phase shift mask, a boundary surface of a 0°-phase region and 180°-phase region of the phase shift mask being provided as a plane structure of the storage electrode; forming a storage electrode photoresist film pattern on the boundary surface by developing the exposed region; and etching the storage electrode conductive layer by using the photoresist film pattern as a mask, the storage electrode being formed by maintaining the storage electrode conductive layer in the plane structure of the storage electrode by generating a micro-loading effect. As a result, the process is simplified to improve a yield, productivity and property of the semiconductor device, and the high integration of the semiconductor device is achieved.

### CROSS-REFERENCES TO RELATED APPLICATIONS

This application claims priority from Korean Application No. 2001-36597, entitled A METHOD FOR FORMING A CAPACITY OF A SEMICONDUCTOR DEVICE, filed Jun. 26, 2001 and incorporated herein by reference.

### BACKGROUND OF THE INVENTION

1. Field of the Invention

The present invention relates to methods for forming a capacitor of a semiconductor device, and in particular to technologies and methods for easily forming a capacitor by using a phase shift mask in a lithography process and by using a micro-loading effect for forming a concave type capacitor.

2. Description of the Background Art

As the size of a cell is reduced due to high integration of a semiconductor device, it becomes more difficult to sufficiently obtain a capacitance proportional to a surface area of a storage electrode. In order to improve integration of the DRAM in which one unit cell is composed of one MOS transistor and one capacitor, a capacitance of the capacitor should be increased and an area of the capacitor should be decreased.

A capacitance C of the capacitor is represented by (∈o×∈r×A)/T, where ∈o denotes a vacuum dielectric constant, ∈r denotes a dielectric constant of the dielectric film, A denotes an area of the storage electrode, and T denotes a thickness of the dielectric film. Accordingly, to increase capacitance C, a high dielectric constant substance is used as a dielectric film, a thickness of the dielectric film is reduced, and/or a surface area of a storage electrode is increased.

Increasing the surface area of the storage electrode, while capable of increasing the capacitance, also complicates the device fabrication process and increases a step difference. As a result, increasing the storage electrode surface area can make it difficult to achieve high integration of the semiconductor device.

Alternatively, a high dielectric film having a high dielectric constant (∈r) is used as the dielectric film, and a metal such as ruthenium (Ru) or platinum (Pt) is employed to form a plate electrode or storage electrode. High dielectric films include Ta₂O₅ film, BST ((Ba,Sr)TiO₃) film, PZT (PbZrTiO₃) film, SBT (SrBi₂Ta₂O₉) film or PLZT (PbLaZrTiO₃) film.

FIGS. 1A to 1E are cross-sectional diagrams illustrating a conventional method for forming a capacitor of a semiconductor device.

Referring to FIG. 1A, a nitride film 13 and an oxide film 15 are formed on a semiconductor substrate 11, and a first photoresist film pattern 17 is formed thereon. Here, the oxide film 15 is a sacrificial oxide film for forming a predetermined shape of a storage electrode, and the first photoresist film pattern 17 is formed by exposure and development processes using a storage electrode mask.

Now referring to FIG. 1B, the oxide film 15 and the nitride film 13 are etched using the first photoresist film pattern 17 as a mask. A storage electrode conductive layer 19 with a predetermined thickness is deposited over the resultant structure, and a second photoresist film 21 is formed to cover the whole upper surface of the resultant structure.

Referring to FIG. 1C, the second photoresist film 21 and the storage electrode conductive layer 19 are etched back until the oxide film 15 is exposed. The second photoresist film 21 remaining after the etch back process is removed. The exposed oxide film 15 is removed according to a wet process (FIG. 1D).

Referring to FIG. 1E, a dielectric film 25 is formed over the resultant structure, and a plate electrode 27 is formed thereon, thereby finishing formation of the concave type capacitor.

FIGS. 2A and 2B are a plan diagram illustrating an exposure mask for the conventional method for forming the capacitor of the semiconductor device, and an SAM photograph showing a resulting photoresist film pattern, respectively.

Referring to FIG. 2A, a chrome pattern 33, which is a shade pattern, is formed on a quartz substrate 31 to form the exposure mask. At this time, the chrome pattern 33 has a rectangular structure of island type to form the storage electrode.

Serifs 35 are formed at the edges of the rectangular structure to prevent a rounding effect. Serifs 35 improve a light image contrast by reducing light diffraction generated at the edges of the rectangular chrome pattern 33 on the mask, to form a good photoresist film pattern. However, the regularity of a line width of the photoresist film pattern is reduced because of an irregular size of the serifs 35.

In addition, when a small line width is required due to high integration of the semiconductor device, a size of the serifs 35 is also decreased. That is, the size of the sheriffs 35 is restricted.

Referring to FIG. 2B, a photoresist film pattern 43 is formed on a semiconductor substrate 41 according to exposure and development processes using the exposure mask of FIG. 2A. FIG. 3 is a cross-sectional SAM photograph showing a pattern shape after the etch back process of the second photoresist film 21 in FIG. 1C.

Referring to FIG. 3, in the DRAM, a storage electrode pattern exists not in a peripheral circuit unit but in a cell unit, and thus the photoresist film coated on the peripheral circuit unit is thicker than that of the cell unit before the etch back process. As a result, the photoresist film remains in the peripheral circuit unit after the etch back process.

In the case that the photoresist film remains in the peripheral circuit unit, the storage electrode substance of the peripheral circuit unit is not etched in the etch back process, and thus the capacitor is not operable.

FIG. 4 is a plan SAM photograph showing a storage electrode 70 that has collapsed due to a contamination of the storage electrode conductive layer in the process of removing the oxide film 15 in FIG. 1D.

As described above, the conventional method for forming the capacitor of the semiconductor device has too many processes, and results in a low yield and productivity of the semiconductor device.

### SUMMARY OF THE INVENTION

The present invention provides methods for forming a capacitor of a semiconductor device which can improve semiconductor device yield and productivity, and achieve high integration of the semiconductor device. Such methods include forming a photoresist film pattern by using a phase shift mask as an exposure mask, and by maintaining a storage electrode conductive layer in a plane structure of a storage electrode by using a micro-loading effect in an etching process of the storage electrode conductive layer.

In one embodiment of the present invention, a method for forming a capacitor of a semiconductor device, includes forming a storage electrode conductive layer on an insulation layer deposited on a semiconductor substrate, and forming a photoresist film on the storage electrode conductive layer. The photoresist film is selectively exposed using a storage electrode phase shift mask. The phase shift mask comprises a one hundred and eighty degree (180°) phase region and a zero degree (0°) phase region. The 180° phase region is defined by a phase shift pattern at a portion of the phase shift mask that corresponds to the storage electrode. The 0° phase region is a remaining portion of the phase shift mask. An edge portion of the 180° phase region is correspondent to the side walls of the storage electrode.

The method further includes forming a storage electrode photoresist pattern by developing the photoresist film, and etching the storage electrode conductive layer using the storage electrode photoresist pattern as a mask. A micro-loading effect is used so that the storage electrode conductive layer remains inside the side walls of the storage electrode, thereby forming the storage electrode.

In one aspect, the phase shift mask is formed by the etching region of a quartz substrate, where a phase difference of light paths passing through two regions is 180° by a predetermined thickness without using a chrome pattern which is a shade pattern. The phase shift mask is embodied to form an island type storage electrode.

A shadow occurs in the boundary surface of the regions having the phase difference in the exposure process using the phase shift mask, and forms a pattern due to a sharply-decreased light strength.

An etching thickness of the quartz substrate for obtaining a phase difference of 180° is represented by λ/2(n−1). Here, λ denotes a wavelength of light, and n denotes a reflective index of the quartz substrate.

### BRIEF DESCRIPTION OF THE DRAWINGS

The present invention will become better understood with reference to the accompanying drawings, which are provided for illustration and thus are not intended to limit the scope of the present invention, wherein:

FIGS. 1 to 4 are relative diagrams illustrating a conventional method for forming a capacitor of a semiconductor device, wherein:

FIGS. 1A to 1E are cross-sectional diagrams illustrating sequential steps of the conventional method for forming the capacitor of the semiconductor device;

FIGS. 2A and 2B are a plan diagram illustrating a mask for the capacitor, and an SAM photograph showing a resulting photoresist film pattern, respectively;

FIG. 3 is an SAM photograph showing a cell unit and a peripheral circuit unit of FIG. 2B;

FIG. 4 is an SAM photograph showing the collapsed capacitor;

FIGS. 5A to 5C are relative diagrams illustrating a method for forming a capacitor of a semiconductor device in accordance with the present invention; and

FIGS. 6A to 6C are cross-sectional diagrams illustrating sequential steps of the method for forming the capacitor of the semiconductor device in accordance with the present invention.

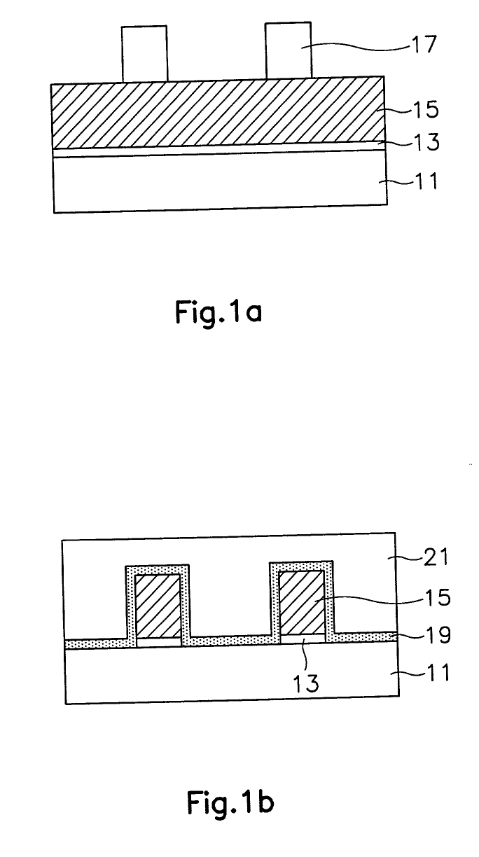

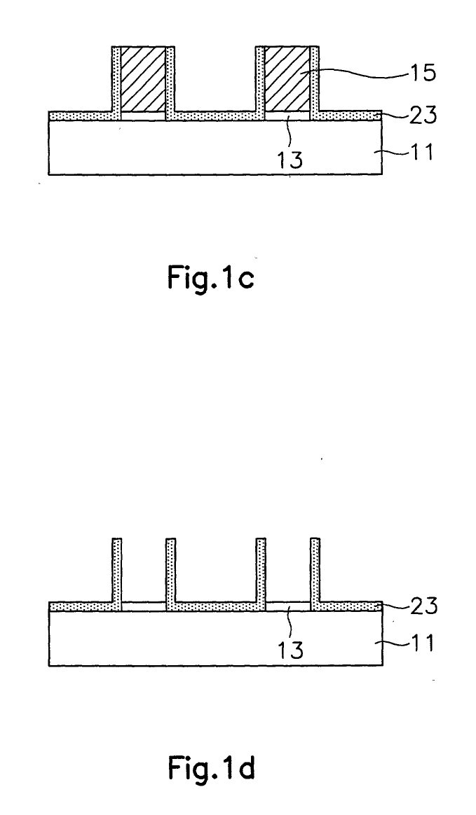

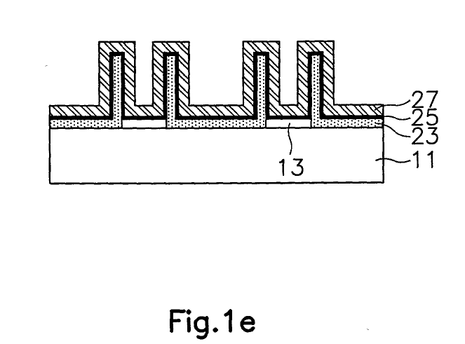

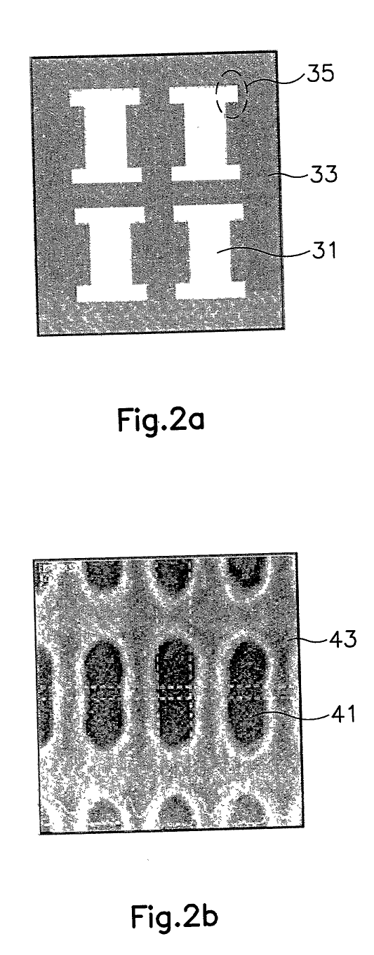

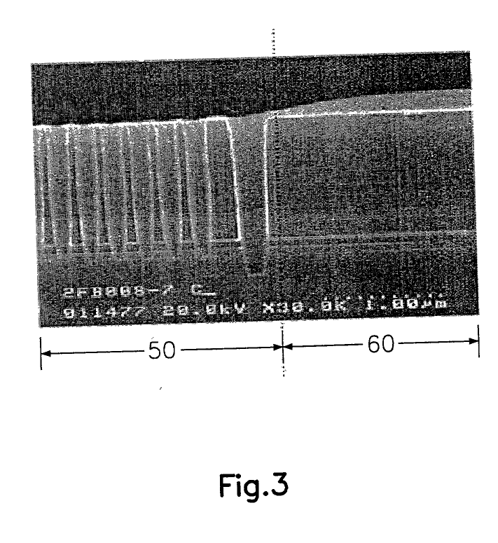

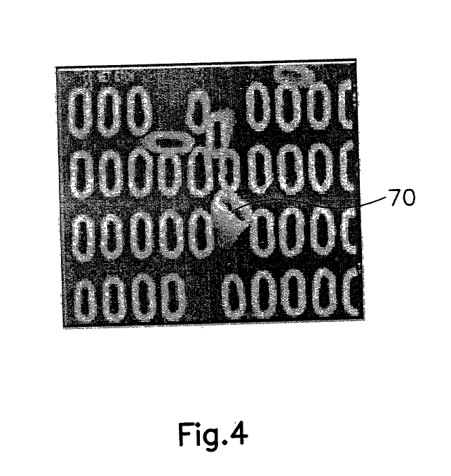

### DETAILED DESCRIPTION OF THE PREFERRED EMBODIMENTS

A method for forming a capacitor of a semiconductor device in accordance with a preferred embodiment of the present invention will now be described in detail with reference to the accompanying drawings.

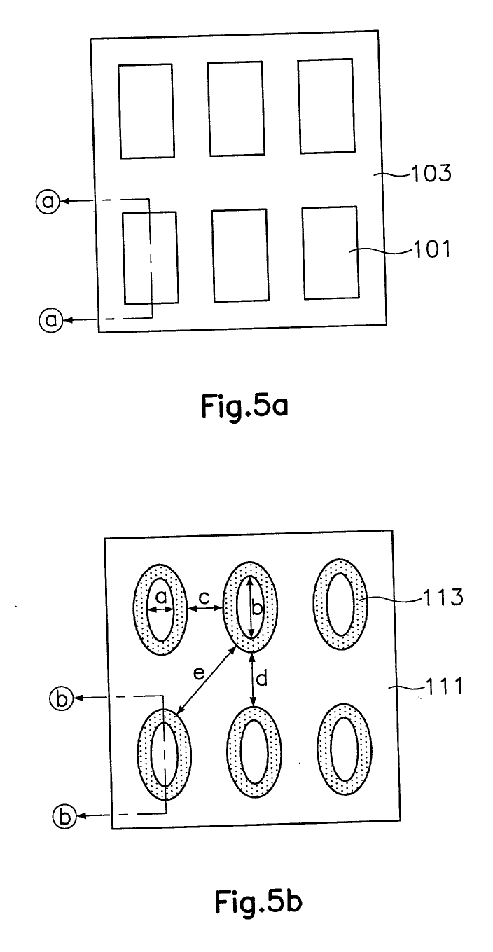

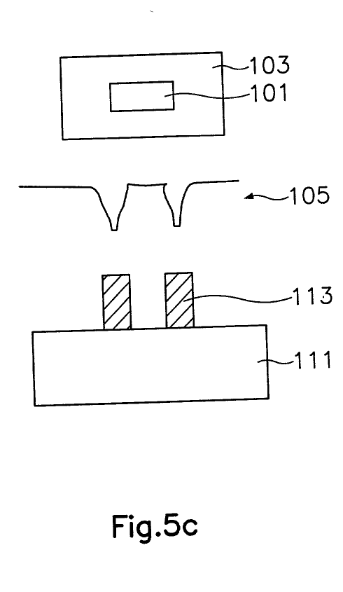

FIGS. 5A to 5C are plan diagrams and cross-sectional diagrams for explaining a principle of the semiconductor device formed in accordance with the present invention.

FIG. 5A is a plan diagram illustrating a storage electrode phase shift mask 100 having a 180 degree phase region 101 and a zero degree phase region 103. The side walls of a concave type storage electrode correspond to an edge of the 180 degree phase region.

FIG. 5B is a plan diagram illustrating a photoresist film pattern 113 formed on the semiconductor substrate 111 according to exposure and development processes using the phase shift mask of FIG. 5A.

FIG. 5C includes a schematic diagram illustrating the phase shift mask of FIG. 5A, a representation of light intensity during an exposure, and the photoresist film pattern 113 formed using the phase shift mask. In particular, a portion for forming one storage electrode pattern is shown. Here, the upper portion of FIG. 5C is taken along line a-a of FIG. 5A, and the lower portion of FIG. 5C is taken along line b-b of FIG. 5B.

The photoresist film pattern 113 is formed on the semiconductor substrate 111 according to the exposure and development processes using the phase shift mask having the zero degree phase region 103 and the 180 degree phase region 101 as an exposure mask.

While the light source reaches to the semiconductor substrate 111 during the exposure process, a remaining image 105 has a reduced light strength along the boundary portion of the two regions, namely, the boundary portion of the zero degree phase region 103 and the 180 degree phase region 101. Thus, the portion having the reduced light strength remains in the development process, to form the photoresist film pattern 113.

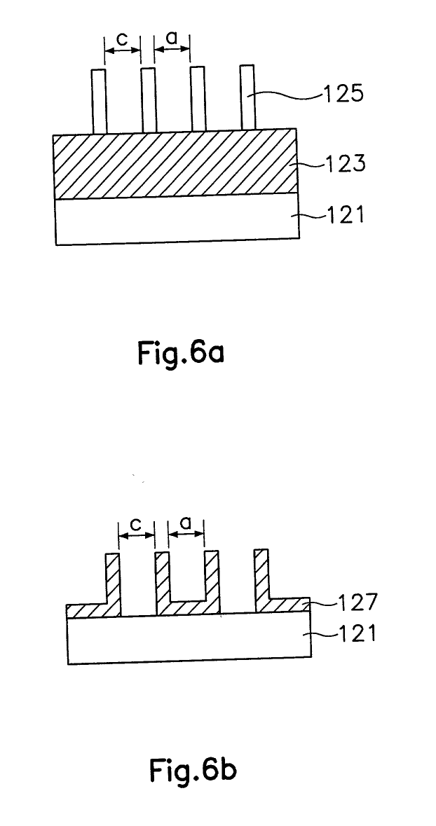

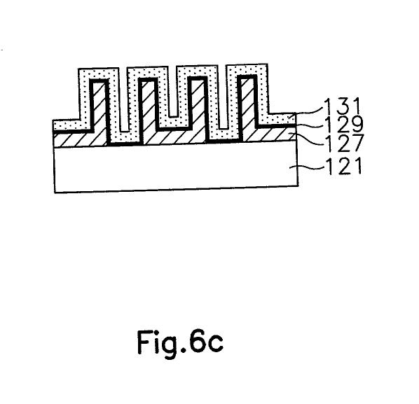

FIGS. 6A to 6C are cross-sectional diagrams illustrating sequential steps of a method for forming the capacitor of the semiconductor device in accordance with the present invention.

A storage electrode conductive layer 123 is formed on a semiconductor substrate 121, and a photoresist film pattern 125 is formed thereon. Here, the storage electrode conductive layer 123 is selected from the group of materials consisting of polysilicon, platinum, iridium, ruthenium, iridium oxide film, ruthenium oxide film, and the like, namely, materials which can be used as a conductive layer in the semiconductor device.

As illustrated in FIGS. 5B and 5C, the photoresist film pattern 125 is formed according to the exposure and development processes using the phase shift mask 100 of FIG. 5A. An interlayer insulating film (not shown) is formed on an element isolating film (not shown), a word line (not shown) and a bit line (not shown), and the storage electrode conductive layer 123 is formed thereon.

Here, the phase shift mask 100 may be formed in various shapes including the rectangular shape. In addition, serifs may be attached to the phase shift mask 100 (FIG. 6a). Thereafter, the storage electrode conductive layer 123 is etched using the photoresist film pattern 125 as a mask to form a storage electrode 127.

The etching process using the photoresist film pattern 125 is performed to generate a micro-loading effect in the etching process of the storage electrode conductive layer 123. The micro-loading effect can be increased by adjusting etching conditions. However, in another embodiment, controlling a pattern density to increase the micro-loading effect is used. That is, in FIGS. 5B, 6A and 6B, dimensions a and b are decreased as much as possible, and c, d and e are increased to prevent plasma penetration to the capacitor. Accordingly, an etching rate of the electrode in the capacitor is reduced, and the micro-loading effect is increased.

The photoresist film pattern 125 is removed (FIG. 6B). A dielectric film 129 is formed on the surface of the storage electrode 127, and a plate electrode 131 is formed thereon, thereby forming the capacitor having a sufficient capacitance to achieve high integration of the semiconductor device.

As discussed earlier, in accordance with the present invention, resolution is improved by employing the phase shift mask as the exposure mask. As a result, the design is simplified without using serifs, the whole process is also simplified to prevent the yield and property of the device from being deteriorated, and the high integration of the semiconductor device is achieved.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A method of forming a capacitor of a semiconductor device having a concave type storage electrode, wherein the concave type storage electrode includes side walls and a bottom portion and is repetitiously arranged in a matrix form, comprising:
forming a storage electrode conductive layer on an insulation layer deposited on a semiconductor substrate;
forming a photoresist film on the storage electrode conductive layer;
selectively exposing the photoresist film using a storage electrode phase shift mask and developing;
wherein the phase shift mask comprises a one hundred and eighty degree (180°) phase region defined by a phase shift pattern at a portion of the phase shift mask which corresponds to the storage electrode, a zero degree (0°) phase region at a remaining portion of the phase shift mask, with an edge portion of the 180° phase region being correspondent to the side walls of the storage electrode;
forming a storage electrode photoresist pattern by developing the photoresist film; and
etching the storage electrode conductive layer using the storage electrode photoresist pattern as a mask, said etching utilizing a micro-loading effect so that the storage electrode conductive layer remains inside the side walls of the storage electrode, thereby forming the storage electrode bottom portion.

2. The method according to claim 1, wherein the storage electrode conductive layer comprises a polysilicon.

3. The method according to claim 1 wherein the storage electrode conductive layer comprises a metal.

4. The method according to claim 1, wherein a thickness difference of a quartz substrate between the 0° phase region and the 180° phase region is λ/2(n−1), wherein λ is a light wavelength and n is a reflective index of the quartz substrate.

5. The method according to claim 1 wherein said phase shift mask comprises a quartz substrate.

6. The method according to claim 5, wherein a thickness difference of the quartz substrate between the 0° phase region and the 180° phase region is λ/2(n−1), wherein λ is a light wavelength and n is a reflective index of the quartz substrate.
